(19) United States
(12) Patent Application Publication
(10) Pub. No.: US 2018/0359346 A1
(43) Pub. Date: Dec. 13, 2018

(54) Rotary Ring Support

(71) Applicant: Lifang CHEN, Shenzhen (CN)

(72) Inventor: Lifang CHEN, Shenzhen (CN)

(21) Appl. No.: 15/655,868

(22) Filed: Jul. 20, 2017

(30) Foreign Application Priority Data
Jun. 12, 2017 (CN) 201720689307.6

(51) Int. Cl. H04M 1/04; F16M 13/00; H05K 5/00; H05K 5/02

(52) U.S. Cl. CPC H04M 1/04; H05K 5/02; H05K 5/0017; F16M 13/00

(57) ABSTRACT

The present invention discloses a rotary ring support including a ring clasp, a rotary element hinged to the ring clasp, and a positioning element connected to the rotary element. The rotary element includes an upper cover hinged to the ring clasp and a bearing having one portion connected to the upper cover and another portion connected to the positioning element. A pivot of the bearing is perpendicular to a flat-panel electronic device, and a pivot of the ring clasp is parallel to the flat-panel electronic device.

### TECHNICAL FIELD

The present invention relates to the technical field of supports for flat-panel electronic devices such as mobile phone and the like, and more particularly to a rotary ring support.

### BACKGROUND

Currently, the flat-panel electronic devices (e.g. smart phones) have very powerful functions, and have been popularly used. The smart phone is no longer a simple tool for communication, but a personal handheld terminal device with integrated functions of calling, text message, network access, movie and TV entertainment and the like. The smart phones are even exaggeratedly described as an extension of the human organs. People are increasingly dependent on mobile phones, and the mobile phone generally has the function to rotate its display screen for operation. In the prior art, some mobile phone supports basically only have functions to provide simple support or protection for the mobile phone and cannot satisfy the requirement of freely rotating the mobile phone. Even worse, the phone are readily to fall down by accident during using. Although there are some ring supports which are possible to rotate to some extent and can prevent the phone from falling down as occurred in the prior art, the rotation of the rings is still greatly limited. As such, the existing rings can only partially meet the requirements of rotation when watching the flat-panel mobile phone.

### SUMMARY OF THE INVENTION

The object of the present invention is to provide a rotary ring support for the flat-panel electronic devices, which aims at solving the problem that the mobile phone support cannot be freely rotated existing in the prior art.

To solve the above-mentioned technical issue, the technical solution provided by the present invention is as follows. A rotary ring support includes a ring clasp, a rotary element hinged to the ring clasp, and a positioning element connected to the rotary element. The rotary element includes an upper cover hinged to the ring clasp, and a bearing having one portion connected to the upper cover while an other portion connected to the positioning element. A pivot of the bearing is perpendicular to a flat-panel electronic device, and a pivot of the ring clasp is parallel to the flat-panel electronic device.

Optionally, the center of the upper cover is provided with a nut post. The rotary element further includes a T-shaped pressure plate having a through hole. An inner ring of the bearing is secured to the upper cover by the T-shaped pressure plate and the nut post.

Optionally, the positioning element includes a cup-shaped bottom cover, and an outer ring of the bearing fits with in the bottom cover.

Optionally, the bottom cover includes a cylindrical portion and an annular flat portion.

Optionally, a bottom surface of the positioning element is bound and positioned to the flat-panel electronic device or a protective cover of the flat-panel electronic device by using a double-sided adhesive.

Optionally, a circular groove is provided in a side of the upper cover facing the ring clasp, and a stainless-steel sheet is disposed inside the circular groove.

Optionally, two lug constructions are symmetrically provided on two outer sides of the upper cover respectively, and two through holes respectively matching with the lug constructions are provided on two ends of the ring clasp.

Optionally, an outer surface of each of the lug constructions is provided with a rib construction in a pivot direction of the ring clasp, and a plurality of grooves fitable with the rib construction are evenly provided on an inner wall of each of the through holes in a circumferential direction.

Optionally, each of the through holes is provided with a decorative plug at an outer side of the inner wall.

Optionally, the upper cover and the positioning element are made of a plastic material.

In some embodiments of the present invention, the bearing provided between the positioning element and the upper cover sufficiently exhibit the rotation characteristic of the bearing, resulting in free rotation of the mobile phones or the flat-panel electronic devices. Such rotation can meet the requirements of the direction adjustment of the display screen while using the mobile phones or flat-panel electronic devices. Furthermore, the mobile phone can be rapidly spinning by the ring being worn around the finger, thereby improving the user experience of man-machine and easing user's pressure.

### BRIEF DESCRIPTION OF THE DRAWINGS

FIG. 1 is a schematic perspective view of a preferred embodiment of the present invention;

FIG. 2 is a schematic sectional view of FIG. 1 with a mobile phone shown;

FIG. 3 is an exploded view of FIG. 1;

FIG. 4 is a schematic perspective view of an upper cover of FIG. 3;

FIG. 5 is an exploded view of the upper cover and an ring clasp shown in FIG. 3;

FIG. 6 is a schematic perspective view of FIG. 1 when combined with the mobile phone.

### DETAILED DESCRIPTION OF THE INVENTION

In order to make the objects and technical solution of the present invention clearer, the present invention will be further described in detail with reference to the accompanying drawings and the embodiments. It is to be understood that the specific embodiments described herein are merely used to illustrate the present invention but not intended to limit.

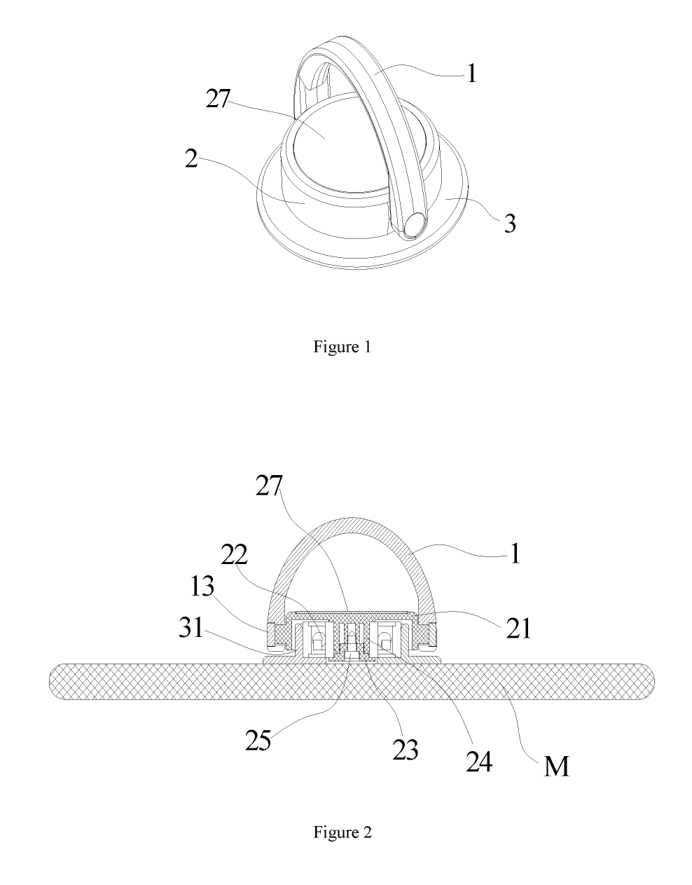

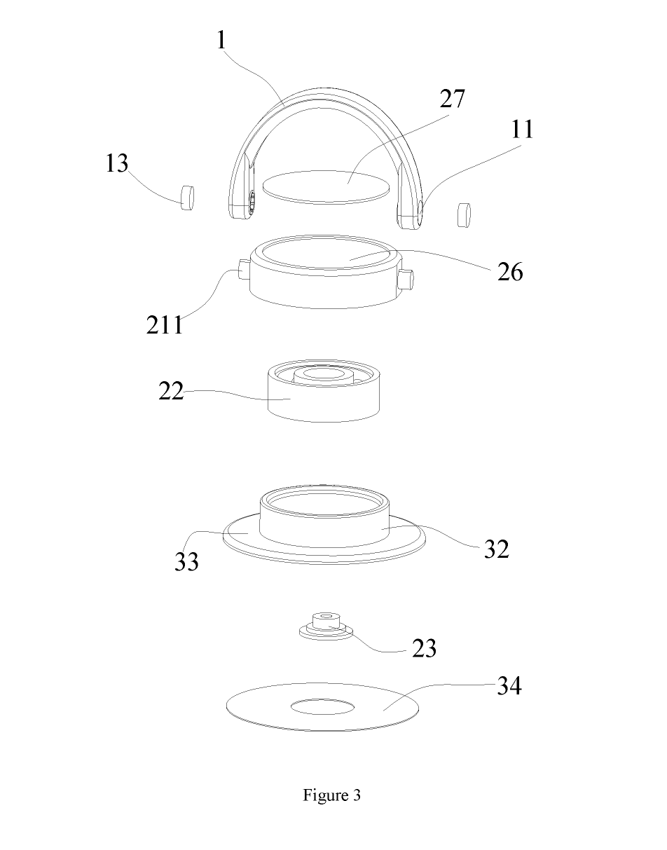

With reference to FIG. 1 to FIG. 3, the present invention provides a rotary ring support including a ring clasp 1, a rotary element 2 hinged to the ring clasp 1, and a positioning element 3 connected to the rotary element 2. The rotary element 2 includes an upper cover 21 hinged to the ring clasp and a bearing 22 having one end connected to the upper cover 21. The other end of the bearing 22 is connected to the positioning element 3. A pivot of the bearing 22 is perpendicular to a flat-panel electronic device M, and a pivot of the ring clasp 1 is parallel to the flat-panel electronic device M. In this way, the mobile phones or the flat-panel electronic devices M can be freely rotated due to the bearing 22 provided between the positioning element 3 and the upper cover 21, with the rotation characteristic of the bearing is sufficiently exhibited. Such rotation can meet the requirements of the direction adjustment of the display screen while using the mobile phones or flat-panel electronic devices. Furthermore, the mobile phone can be rapidly spinning by the ring being worn around the finger, thereby improving the user experience of man-machine and easing user's pressure.

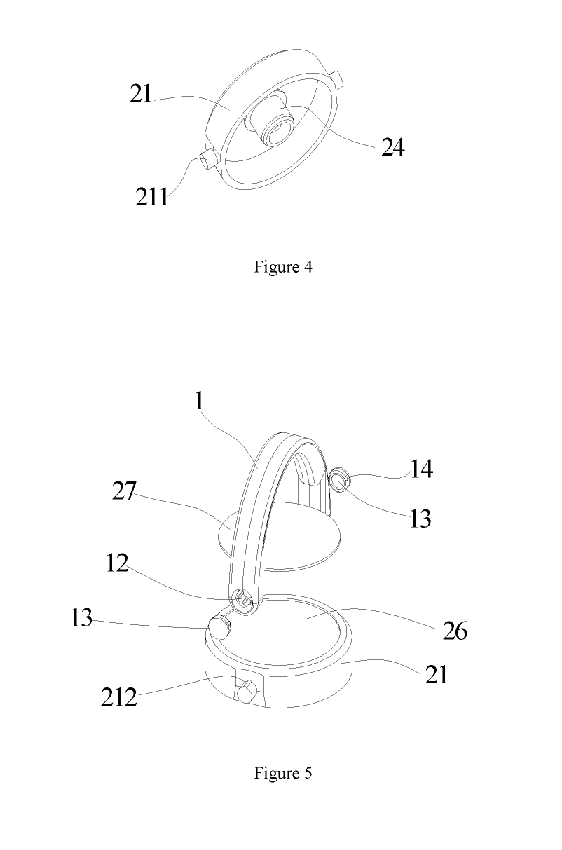

With reference to FIG. 4, in order to achieve the mounting and position between the upper cover 21 and the bearing 22, the center of the upper cover 21 is provided with a nut post 24. The rotary element 2 further includes a pressure plate 23 having a through hole. Preferably, the pressure plate 23 is T-shaped. The inner ring of the bearing is secured to the upper cover 21 by means of the T-shaped pressure plate 23 and the nut post 24. More specifically, the inner ring of the bearing 22 is mounted around the nut post 24, and the T-shaped pressure plate 23 is mounted to a distal end of the nut post 24 with a radially outer edge axially abutting against an axial end of the inner ring of the bearing 22. A bolt 25 is then provided to go through the T-shaped pressure plate 23 and screw into the nut post 24 and thus get fastened, such that the inner ring of the bearing is secured to the upper cover 21.

The positioning element 3 includes a cup-shaped bottom cover 31, and an outer ring of the bearing is embedded in the bottom cover 31. The bottom cover 31 comprises a cylindrical portion 32 and an annular flat portion 33. The outer ring and the inner ring of the bearing 22 are rotatable relative to each other, such that the rotary element 2 connected with the inner ring of the bearing 22 is rotatable with respect to the positioning element 3 which is connected with the outer ring of the bearing 22.

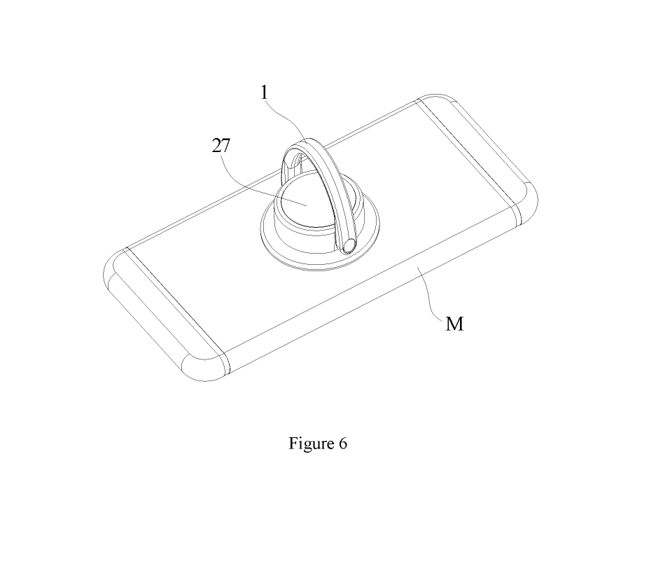

With reference to FIG. 6, in order to achieve mechanical connection with the flat-panel electronic device, e.g., the mobile phone, the bottom surface of the positioning element 3 is bound and positioned to the flat-panel electronic device or a protective cover of the flat-panel electronic device by using a double-sided adhesive 34 (e.g. 3M double-sided adhesive) in the embodiment.

A circular groove 26 is defined in a side of the upper cover 21 facing the ring clasp 1, and a plate sheet is disposed inside the circular groove 26. Preferably, the plate sheet is a stainless-steel sheet 27. The stainless-steel sheet 27 may be decorative and provided with various patterns thereon. Since different flat-panel electronic devices (e.g. the mobile phones) may present different colors, the stainless-steel sheet 27 may be selected to have the color or pattern matching with the flat-panel electronic devices such as mobile phones. As the stainless-steel sheet 27 is separately formed, such construction contributes to reduce the manufacturing cost.

With reference to FIG. 5, in order to achieve the mechanical connection with the ring clasp 1, two lug construction 211 are symmetrically provided on two outer sides of the upper cover 21, respectively. Two through hole 11 respectively matching with the lug constructions 211 are provided on two ends of the ring clasp 1. The lug construction and the through hole match with each other and fit together to achieve a hinged connection.

In order to facilitate the adjustment of the angle of the mobile phone, an outer surface of the lug construction 211 is provided with a rib construction 212 in a pivot direction of the ring clasp 1, and a plurality of grooves 12 which are fitable with the rib construction 212 are evenly provided in an inner wall of the through hole 11 in a circumferential direction. In this embodiment, there are one rib construction 212, and eight grooves 12 arranged in the inner wall of the through hole 11. The grooves 12 are arranged at an equal angle, such that users may have much more options to select a proper angle of the mobile phone.

With reference to FIG. 5, in order to improve the aesthetic of the electronic device, two through holes 11 each are provided with a decorative plug 13 at outer side of the inner walls. A plurality of protrusions 14 are provided on the outer side wall of the decorative plug 13 at an equal angle.

In this embodiment, the upper cover 21 and the positioning element 3 are made of a plastic material to reduce the overall weight of the entire device. However, the bearing 22 is made of a metallic material, and the flexibility of the plastic material is greater than that of the metallic material. This combination of metal and plastic material contributes to good mounting and positioning performance, and reduces the noise that may generate during the rapid spinning of the phone, thereby improving the user experience.

Those aforementioned are only preferred embodiments of the present invention, and are not intended to limit the present invention. Any modifications, equivalents, and improvements within the spirit and principles of the present invention should all be deemed as falling within the protection scope of the present invention.

What is claimed is:

1. A rotary ring support, comprising:
a ring clasp;
a rotary element hinged to the ring clasp; and
a positioning element connected to the rotary element,
wherein the rotary element comprises an upper cover hinged to the ring clasp and a bearing having one portion connected to the upper cover and another portion connected to the positioning element, a pivot of the bearing is perpendicular to a flat-panel electronic device, and a pivot of the ring clasp is parallel to the flat-panel electronic device.

2. The rotary ring support of claim 1, wherein the upper cover is provided with a nut post, the rotary element further comprises a T-shaped pressure plate having a through hole, and an inner ring of the bearing is secured to the upper cover by the T-shaped pressure plate and the nut post.

3. The rotary ring support of claim 1, wherein the positioning element comprises a cup-shaped bottom cover, and an outer ring of the bearing fits within the bottom cover.

4. The rotary ring support of claim 3, wherein the bottom cover comprises a cylindrical portion and an annular flat portion.

5. The rotary ring support of claim 3, wherein a bottom surface of the positioning element is bound and positioned to the flat-panel electronic device or a protective cover of the flat-panel electronic device by using a double-sided adhesive.

6. The rotary ring support of claim 1, wherein a circular groove is provided in a side of the upper cover facing the ring clasp, and a stainless-steel sheet is disposed inside the circular groove.

7. The rotary ring support of claim 1, wherein two lug constructions are symmetrically provided on two outer sides of the upper cover respectively, and two through holes respectively matching with the lug constructions are provided on two ends of the ring clasp.

8. The rotary ring support of claim 7, wherein an outer surface of each of the lug constructions is provided with a rib construction in a pivot direction of the ring clasp, and a plurality of grooves fitable with the rib construction are evenly provided on an inner wall of each of the through holes in a circumferential direction.

9. The rotary ring support of claim 8, wherein each of the through holes is provided with a decorative plug at an outer side of the inner wall.

10. The rotary ring support of claim 1, wherein the upper cover and the positioning element are made of a plastic material.
